(19) United States
(12) Patent Application Publication
(10) Pub. No.: US 2026/0107799 A1
(43) Pub. Date: Apr. 16, 2026

(54) SUBSTRATE STRUCTURE

(71) Applicant: SILICONWARE PRECISION INDUSTRIES CO., LTD., Taichung City (TW)

(72) Inventors: Chieh-Yi HSIEH, Taichung City (TW); Jui-Kun WANG, Taichung City (TW); Fang-Wei CHANG, Taichung City (TW); Chih-Wen FAN, Taichung City (TW); Hsiu-Fang CHIEN, Taichung City (TW)

(73) Assignee: SILICONWARE PRECISION INDUSTRIES CO., LTD., Taichung City (TW)

(21) Appl. No.: 19/061,396

(22) Filed: Feb. 24, 2025

(30) Foreign Application Priority Data
Oct. 16, 2024 (TW) 113139388

(51) Int. Cl. H01L 23/498

(52) U.S. Cl. CPC H10W 70/65

(57) ABSTRACT

Provided is a substrate structure including a substrate body and a plurality of insulating blocks. The substrate body has a circuit layer and is defined with a chip placement area. The plurality of insulating blocks are disposed on the substrate body in the chip placement area and cover part of the circuit layer to reduce the ratio of the exposed circuit layers, thereby the delamination problem can be eliminated.

### BACKGROUND

### 1. Technical Field

The present disclosure relates to a substrate structure, and more particularly, to a substrate structure that can reduce the problem of delamination.

### 2. Description of Related Art

With the development of the electronics industry, today's electronic products are designed towarding the direction of being light, thin, short, and diversified in functions. Accordingly, semiconductor packaging technology has also developed different packaging types. In order to meet the high integration and miniaturization requirements of semiconductor devices, the industry mostly adopts flip chip packaging structures.

FIG. 1A and FIG. 1B are respectively a schematic cross-sectional view and a partial top view of a conventional flip chip package 1. As shown in FIG. 1A, a package substrate 10 has a circuit layer 100 composed of copper wires, an insulating protective layer 101 and an opening 102 for exposing the circuit layer 100, and the package substrate 10 is defined with a chip placement area D. A semiconductor chip 11 is bonded to the circuit layer 100 in the chip placement area D of the package substrate 10 via a plurality of solder bumps 12, and then an underfill 13 is formed between the semiconductor chip 11 and the package substrate 10 to cover the plurality of solder bumps 12. However, the bonding between the underfill 13 and the circuit layer 100 in the chip placement area D is poor due to large-area contact, which easily leads to the delamination problem, and the underfill 13 and the package substrate 10 are also easily separated from each other. In addition, single opening 102 with the large area can easily cause the flow rate of the primer 13 to slow down, which can easily lead to the problem of air bubbles.

Therefore, how to overcome the above-mentioned deficiencies in the prior art has become a technical problem that needs to be solved urgently.

### SUMMARY

The present disclosure provides a substrate structure comprises a substrate body having a circuit layer formed on a surface thereof, wherein the surface of the substrate body is defined with a chip placement area; and a plurality of insulating blocks formed on the surface of the substrate body and located in the chip placement area to cover a portion of the circuit layer.

In the aforementioned substrate structure, a separation distance is present between any two adjacent ones of the plurality of insulating blocks.

In the aforementioned substrate structure, the separation distance is greater than 70 μm.

In the aforementioned substrate structure, the circuit layer includes a plurality of electrical contact pads for electrically connecting an electronic component in the chip placement area, and a separation distance is present between any one of the plurality of insulating blocks and a corresponding one of the plurality of electrical contact pads.

In the aforementioned substrate structure, the separation distance is greater than 20 μm.

In the aforementioned substrate structure, the shape of each of the plurality of insulating blocks is a circle.

In the aforementioned substrate structure, the circle has a diameter of greater than 100 μm.

In the aforementioned substrate structure, the substrate structure further comprises an insulating protective layer formed on the surface of the substrate body and having at least one opening corresponding to the chip placement area and exposing a portion of the circuit layer.

In the aforementioned substrate structure, the plurality of insulating blocks are disposed in the opening in the chip placement area and are spaced apart from the insulating protective layer.

In the aforementioned substrate structure, a portion of the opening is located within the chip placement area, and the remaining portion thereof is located outside the chip placement area.

To sum up, in the substrate structure of the present disclosure, by arranging the plurality of insulating blocks in the chip placement area on the surface of the substrate body, the plurality of insulating blocks can cover the portion of the circuit layer, thereby the ratio of the exposed copper can be effectively reduced. In addition, the contact area between the underfill and the copper is reduced, so as to improve the delamination problem and effectively increase the flow rate of the underfill to avoid the formation of air bubbles.

### BRIEF DESCRIPTION OF THE DRAWINGS

FIG. 1A and FIG. 1B are respectively a schematic cross-sectional view and a partial top view of a conventional flip chip package structure.

FIG. 2 is a schematic top view of a substrate structure according to the present disclosure.

FIG. 3 is a partially enlarged schematic view of the substrate structure according to the present disclosure.

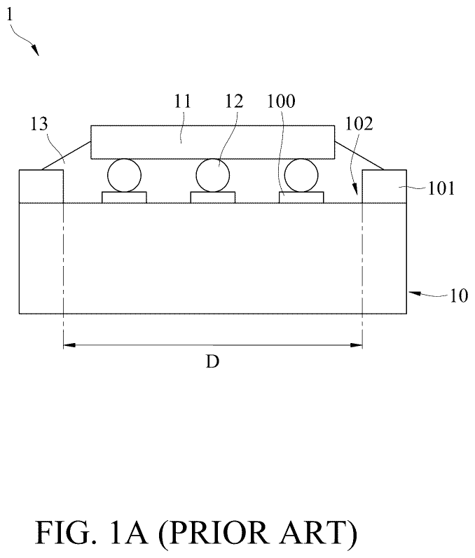

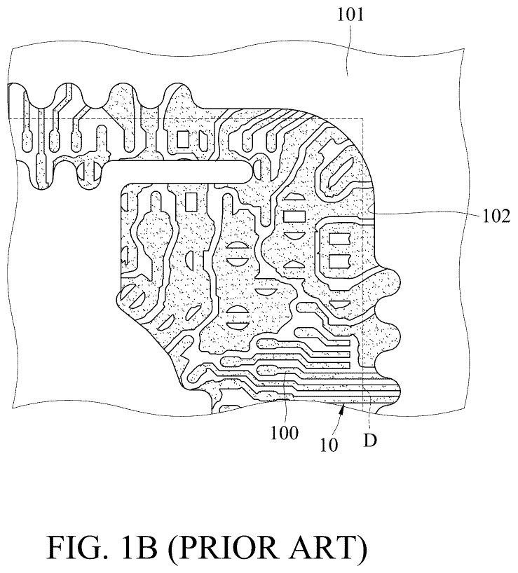

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

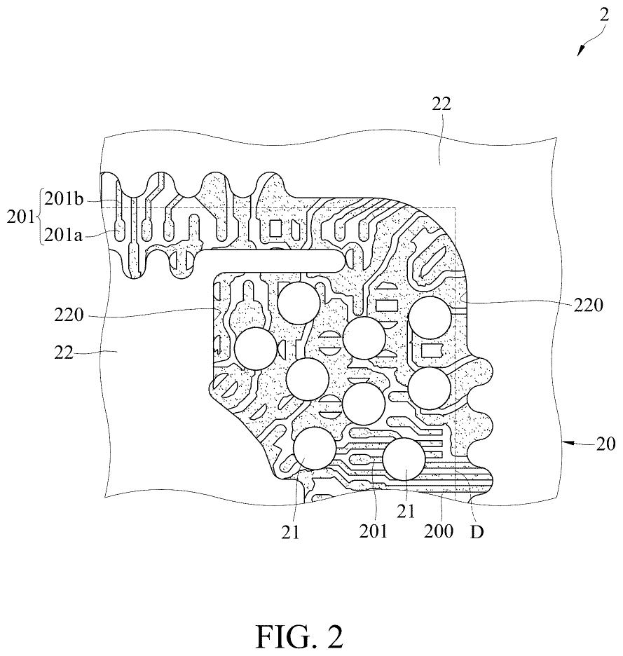

FIG. 2 is a schematic top view of a substrate structure 2 according to the present disclosure. As shown in FIG. 2, the substrate structure 2 is, for example, a package substrate for carrying a semiconductor chip, and the package substrate includes a substrate body 20 and a plurality of insulating blocks 21.

The substrate body 20 is, for example, a substrate with a core or a coreless substrate. A circuit layer 201 is disposed on a surface 200 of the substrate body 20, and the surface 200 is defined with a chip placement area D.

In this embodiment, the substrate body 20 includes at least one insulating layer and at least one wiring layer (both are not shown) formed on the insulating layer. The wiring layer may be, for example, a fan out type redistribution layer (RDL), with an outermost wiring layer serving as the circuit layer 201. The circuit layer 201 includes a plurality of electrical contact pads 201a and a plurality of conductive traces 201b connected to the electrical contact pads 201a. The chip placement area D is used for disposing an electronic components such as a semiconductor chip or a passive element. For example, the electronic component is connected to the electrical contact pads 201a via the conductive bumps to form an electronic package.

Furthermore, materials for forming each wiring layers are copper, and each insulating layer is, for example, polybenzoxazole (PBO), polyimide (PI), prepreg (PP) and other dielectric materials.

An insulating protective layer 22 is formed on the surface 200 of the substrate body 20, and the insulating protective layer 22 has at least one opening 220. In one embodiment, the opening 220 corresponds to the chip placement area D and exposes a portion of the circuit layer 201, a portion of the opening 220 is located in the chip placement area D, and the remaining portion of the opening 220 is located outside the chip placement area D. The opening 220 located outside the chip placement area D allows the underfill to effectively flow into a space between the electronic component and the substrate body 20.

Furthermore, the material of the insulating protective layer 22 may be, for example, solder mask, ink, or other solder resist materials.

A plurality of insulating blocks 21 are disposed on the surface 200 of the substrate body 20 and are located in the opening 220 in the chip placement area D to cover a portion of the circuit layer 201. Furthermore, the plurality of insulating blocks 21 are spaced apart from each other and from the insulating protective layer 22.

In addition, the material of each of the insulating blocks 21 can be, for example, solder resist material such as solder mask, ink, and the like, and the material of the each of the insulating blocks 21 can be the same as the material of the insulating protective layer 22. Furthermore, the material of each of the insulating blocks 21 may also be different from the insulating protective layer 22, but the present disclosure is not limited to as such.

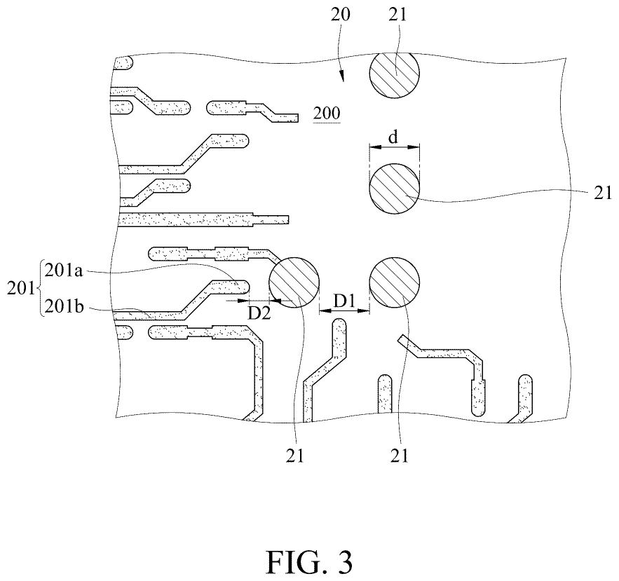

As shown in FIG. 3, a separation distance D1 is present between any two adjacent insulating blocks 21. The separation distance D1 is greater than 70 μm, and may be for example but not limited to 80 μm. The problem of air bubbles generated when the underfill flows in the opening 220 can be avoided by the separation distance D1 between any two adjacent insulating blocks 21.

Furthermore, a separation distance D2 is also present between any insulating block 21 and any the electrical contact pads 201a. The separation distance D2 is greater than 20 μm, for example, the separation distance D2 can be 30 μm, but not limited thereto. The separation distance D2 can effectively improve the workability of substrate.

In addition, a shape of each of the insulating blocks 21 is a circle with a diameter d, and the diameter d is greater than 100 μm, for example, the diameter d can be 125 μm, preferably 110 μm, but the present disclosure is not limited to as such.

To sum up, in the substrate structure of the present disclosure, by arranging a plurality of insulating blocks in the chip placement area on the surface of the substrate body, the plurality of insulating blocks can cover the portion of the circuit layer, thereby the ratio of the exposed copper (the circuit layer) can be effectively reduced. In addition, the contact area between the underfill and the copper is reduced, so as to improve the delamination problem and effectively increase the flow rate of the underfill to avoid the generation of air bubbles.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A substrate structure, comprising:
a substrate body having a circuit layer formed on a surface thereof, wherein the surface of the substrate body is defined with a chip placement area; and
a plurality of insulating blocks formed on the surface of the substrate body and located in the chip placement area to cover a portion of the circuit layer.

2. The substrate structure of claim 1, wherein a separation distance is present between any two adjacent ones of the plurality of insulating blocks.

3. The substrate structure of claim 2, wherein the separation distance is greater than 70 μm.

4. The substrate structure of claim 1, wherein the circuit layer includes a plurality of electrical contact pads for electrically connecting an electronic component in the chip placement area, and a separation distance is present between any one of the plurality of insulating blocks and a corresponding one of the plurality of electrical contact pads.

5. The substrate structure of claim 4, wherein the separation distance is greater than 20 μm.

6. The substrate structure of claim 1, wherein a shape of each of the plurality of insulating blocks is a circle.

7. The substrate structure of claim 6, wherein the circle has a diameter of greater than 100 μm.

8. The substrate structure of claim 1, further comprising an insulating protective layer, formed on the surface of the substrate body and having at least one opening corresponding to the chip placement area and exposing a portion of the circuit layer.

9. The substrate structure of claim 8, wherein the plurality of insulating blocks are disposed in the opening in the chip placement area and are spaced apart from the insulating protective layer.

10. The substrate structure of claim 8, wherein a portion of the opening is located within the chip placement area, and the remaining portion thereof is located outside the chip placement area.
